(19) United States
(12) Patent Application Publication
(10) Pub. No.: US 2013/0277693 A1
(43) Pub. Date: Oct. 24, 2013

(54) LIGHT EMITTING DIODE (LED) COMPONENT WITH HIGH SIGNAL-TO-NOISE RATIO

(71) Applicant: DOMINANT OPTO TECHNOLOGIES SDN. BHD., (US)

(72) Inventors: Tek Beng LOW, Melaka (MY); Eng Wah TAN, Melaka (MY); Chee Sheng LIM, Melaka (MY)

(21) Appl. No.: 13/847,811

(22) Filed: Mar. 20, 2013

(30) Foreign Application Priority Data
Mar. 21, 2012 (MY) PI 2012001276

(51) Int. Cl. H01L 33/50

(52) U.S. Cl. CPC H01L 33/502
USPC 257/89

(57) ABSTRACT

The invention relates to a light emitting diode (LED) component that is assembled with a plurality of LED chips, incorporating luminescence conversion element and is characterized by a wide color spectrum ranging from 400 nm to 680 nm and has a high signal-to-noise ratio for each of the peak wavelength in the spectrum.

### FIELD OF INVENTION

The invention relates to a light emitting diode (LED) component that is assembled with a plurality of LED chips, incorporating luminescence conversion element and is characterized by a wide color spectrum ranging from 400 nm to 680 nm and has a high signal-to-noise ratio for each of the peak wavelength in the spectrum. Such a LED component is highly desirable for back-light applications in displays as the white light source. With the said color spectrum, such display system can easily achieve high color rendering capability.

### PRIOR ART

Optoelectronic components such as light emitting diode (LED) are widely used in the world today especially for lighting and as signaling devices. Conventional LED naturally are capable of generating saturated colours ranging from long wavelength such as red to shorter wavelength such as blue at the other end of the spectrum; depending on the semiconductor material used to manufacture the LED chip. GaP and AlInGaP material are commonly used to generate colours in the red, orange and yellow spectrum. As for blue, GaN and InGaN are used instead.

Another area of application of LED is as the white light source in back-light applications for displays such as the liquid crystal display (LCD). The traditional light source has always been the fluorescent lamp. However, due better energy efficiency and more robust construction, LED is rapidly replacing fluorescent lamp. There are two main approaches in the use of LED for back-light applications. One of the approaches is the use of a multi-chip component; comprising of red, green and blue chips. The chips' optical characteristics are selected and driven at specific current in order to generate a combined white light. This method is difficult as it involves tight selection for each of the chips' characteristics. The specific drive current for each chip also increase the complexity of the drive circuit. These in turns make the solution costly.

Alternatively, white light source can also be generated using a single chip configuration coupled with luminescence conversion element. Such method for instance is described by Hohn et al. in U.S. Pat. No. 6,066,861. The patent described the method where a luminescence conversion element is used to convert a portion of a primary wavelength emitted by a semiconductor chip into radiation of a longer wavelength. This makes it possible to produce a component which radiates polychromatic white light with a single light-emitting semiconductor chip. Typically a blue chip is used as the light source and a yellow luminescence conversion element is used to convert a portion of the blue light into a broad spectrum of yellow light. The combination of this spectrum then produces the required white light.

Besides yellow luminescence conversion element, today's technology also includes the use of multiple luminescence conversion elements such as red and green phosphor. The solution using multiple phosphors is more superior as the resulting white light contain a wider spectrum of light especially the longer wavelength portions generated by the red phosphor. This will lead to a display with a higher color rendering capability.

Besides the need for wide color spectrum content, the signal-to-noise ratio of the three key colors; red, green and blue is another important parameter that will influence the color rendering capability of a display. Ideally, the multi-chip component consisting of a red, green and blue chip would provide the best signal-to-noise ratio performance. This is inherently due to the narrow band-width characteristics of LED. A typical spectrum of such multi-chip component is shown in FIG. 1. The color spectrum is wide ranging from the short wavelength generated by to blue chip to the long wavelength generated by the red chip. The typical band-width of each of the peak is only in the range of 20-50 nm. As all the three peaks; each for red, green and blue are well spaced apart; the signal-to-noise for each of the color component is very high and is highly desirable for back-light display. However, as explained earlier, multi-chip component solution is difficult and expensive to implement.

Alternatively, multiple phosphors system; a blue chip incorporating green and red phosphor may be a better and more practical solution. A typical spectrum of such system is shown in FIG. 2. The blue peak is generated by the blue chip and the green and red are generated by phosphors. The color spectrum is also wide similar to the multi-chip system. However, the signal-to-noise is poor. This is obvious by analyzing the “peaks and valleys” in the spectrum. The relative intensity of the respective peaks for green and red are not significantly high.

This patent will try to describe an alternative method to generate a white light source for back-light applications that is able to support a wide color spectrum, good signal-to-noise ratio and cost effective.

### DESCRIPTION OF DRAWINGS

The drawings enclosed are as follows:

FIG. 1 is the typical spectrum of such multi-chip component;

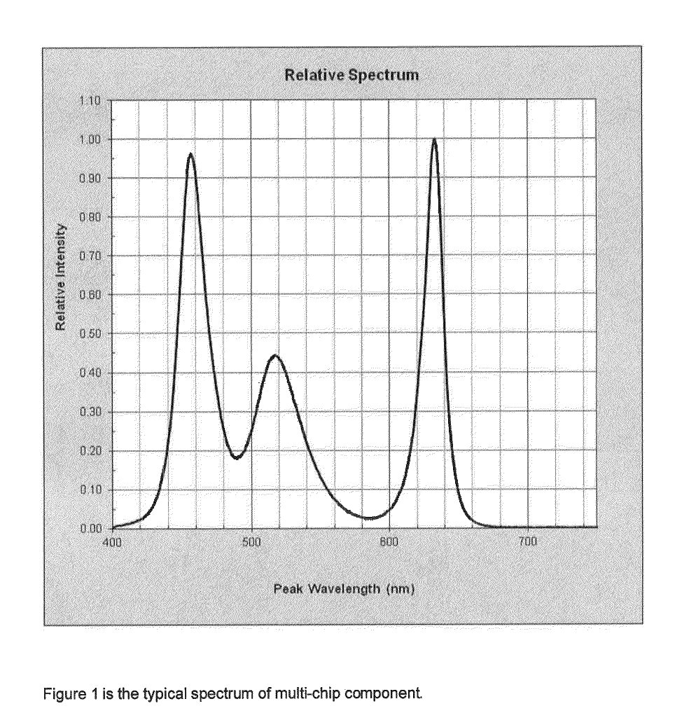

FIG. 2 is the typical spectrum of a multiple phosphors system; incorporating green and red phosphor;

FIG. 3 is the typical spectrum in accordance to the invention.

FIG. 4 is the schematic view of the first exemplary embodiment of a LED component according to the invention;

### DETAIL DESCRIPTION

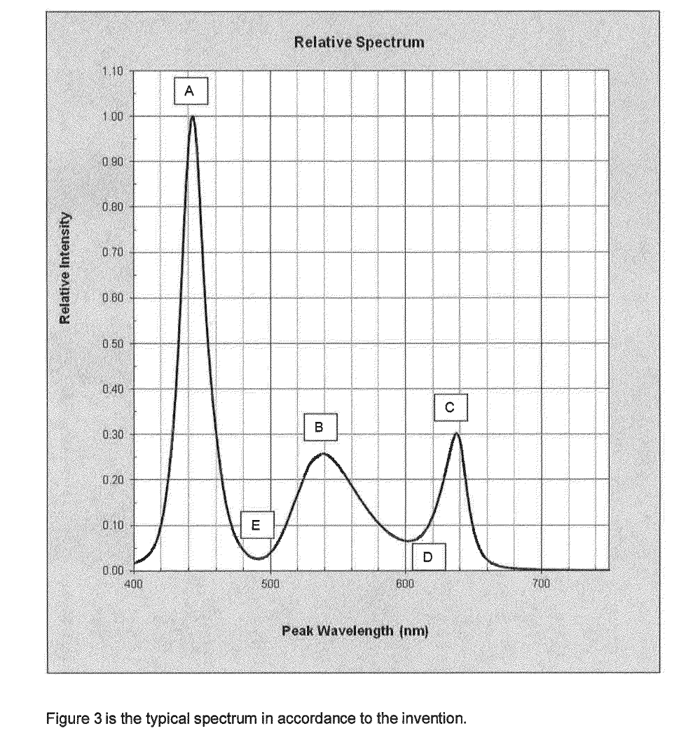

The invention relates to a light emitting diode (LED) component that is assembled with a plurality of LED chips, incorporating luminescence conversion element and is characterized by a wide color spectrum ranging from 400 nm to 680 nm and has a high S signal-to-noise ratio for each of the peak wavelength in the spectrum. A typical spectrum for the invention is as shown in FIG. 3. Such a LED component is highly desirable for back-light applications in displays as the white light source. With the said color spectrum, such display system can easily achieve high color rendering capability.

In accordance to the present invention, the light emitting diode (LED) component is assembled with a plurality of LED chips. In order to simplify the application of such component, all the LED chips are electrically connected in series. In this manner, applications will not require multiple electrical drive channels. The LED component will have very similar electrical characteristics as any standard LEDs in the industry except for the higher forward voltage due to the serial connection of the chips. The higher voltage will not pose any technical constraints as electrical drivers available today are able to handle the requirement.

The string of LED chips can be divided into two groups. The first group of chips will have a peak wavelength in the range of 400 nm to 470 nm. The second group of chips will have much longer wavelength in the range of 615 nm to 650 nm. The total light output from the first and second group is different. The actual proportion of each group has to be tuned in order to achieve at the desired white color coordinate.

A luminescence conversion element is then incorporated into the component. This luminescence conversion element is typically selected to have a peak emission in the range of 520 nm to 560 nm and is excited by shorter wavelength emissions. Suitable materials with such conversion properties include LuAG, silicates and nitrides. In accordance to the present invention, the light output from the first group of chips having short wavelength in the range of 400 nm to 470 nm will be used to excite the luminescence conversion element. The combination of light from the first group of chips, emission from the luminescence conversion element and the light from the second group of chips will generate the resultant white light. The typical spectrum of such light is as shown in FIG. 3.

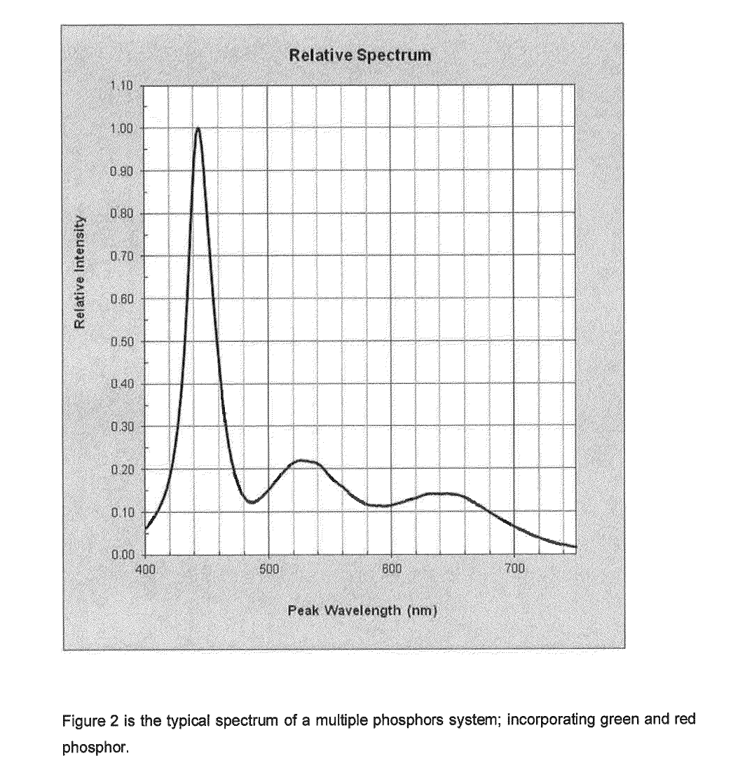

As shown in FIG. 3, three distinct peaks can be observed. The total color spectrum is wide and span from a minimum of 400 nm to a maximum of 680 nm. In addition, the signal-to-noise ratio for each of the peak is greater than three times. The signal-to-noise ratio is derived by dividing the respective intensity at the peak (indicated by A,B and C) against the noise level (indicated by D and E). Such high signal-to-noise ratio is not achievable by using multiple phosphor system approach as shown in FIG. 2. Such system can only achieve signal-to-noise ratio in the range of 1.5 to 2.0 times.

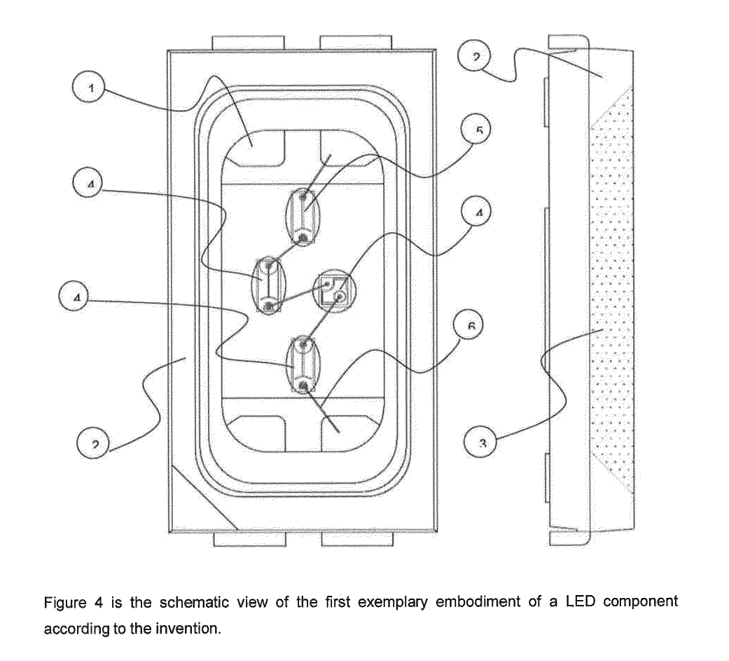

In an embodiment of the present invention, FIG. 4 is a schematic view of the first exemplary embodiment of a LED component according to the invention. The LED component is made up of a lead-frame (1) and a housing (2) is molded around the lead frame. This lead frame can be made out of metal such as copper or copper alloy. The housing is normally molded out of conventional engineering plastic such as PPA or high temperature nylon. In the housing, a cavity (3) is formed so that semiconductor chips (4,5) can be attached to the lead frame. As shown in FIG. 4, 2 different groups of semiconductor chips (4,5) are attached on the lead-frame. The first group of chips (4) will have a peak wavelength in the range of 400 nm to 470 nm. The second group of chips (5) will have much longer wavelength in the range of 615 nm to 650 nm. The chips are connected in such a way whereby the electrical circuit is in a string of series connection. Normally the connection is done using a metallic wire (6) such as gold wire. A standard industry thermosonic wire bond process will be able to perform this connection. The cavity is then filled with an encapsulation material such as silicone or epoxy. The encapsulation material is mixed with a luminescence conversion element. This luminescence conversion element is typically selected to have a peak emission in the range of 520 nm to 560 nm. Suitable materials with such conversion properties include LuAG, silicates and nitrides.

1. A light emitting diode (LED) component that is assembled with a plurality of LED chips, incorporating luminescence conversion element and is characterized by a wide color spectrum ranging from 400 nm to 680 nm and has a high signal-to-noise ratio for each of the peak wavelength in the spectrum.

2. A light emitting diode (LED) component as stated in claim 1, where the signal-to-noise ratio for each of the peak in the spectrum is greater than three times.

3. A light emitting diode (LED) component as stated in claim 1, where there are two groups of chips in the component.

4. A light emitting diode (LED) component as stated in claim 3, where the first group of chips will have a peak wavelength in the range of 400 nm to 470 nm and the second group of chips will have longer wavelength in the range of 615 nm to 650 nm.

5. A light emitting diode (LED) component as stated in claim 1, where the luminescence conversion element is selected to have a peak emission in the range of 520 nm to 560 nm.
